(19) United States
(12) Patent Application Publication
(10) Pub. No.: US 2025/0183866 A1
(43) Pub. Date: Jun. 5, 2025

(54) WAFER-LEVEL PACKAGED RESONATOR AND PREPARATION METHOD THEREFOR, AND ELECTRONIC DEVICE

(71) Applicants: TKD Science and Technology Co., LTD., Suizhou (CN); HUAZHONG UNIVERSITY OF SCIENCE&TECHNOLOGY, WUHAN (CN)

(72) Inventors: Yang WAN, Suizhou (CN); Xiaowei ZHANG, Suizhou (CN); Mingfan LIU, Suizhou (CN); Kang PENG, Suizhou (CN)

(21) Appl. No.: 18/966,183

(22) Filed: Dec. 3, 2024

(30) Foreign Application Priority Data
Dec. 4, 2023 (CN) 202311643222.0

(51) Int. Cl. H03H 3/02; H03H 9/19

(52) U.S. Cl. CPC H03H 3/02; H03H 9/19

(57) ABSTRACT

Provided are a wafer-level packaged resonator and a preparation method therefor, as well as an electronic device, relating to the technical field of resonators. The electronic device includes a wafer-level packaged resonator. The wafer-level packaged resonator includes a wafer top cover, a wafer base, and a blank. The blank includes: a resonant part; an assembling part sleeved on the periphery of the resonant part, where the blank is bonded and packaged between the wafer top cover and the wafer base through the assembling part; and at least two connecting parts, connected between the resonant part and the assembling part, respectively, where each connecting part includes at least one continuous bend.

### CROSS-REFERENCE TO RELATED APPLICATIONS

The present application is based upon and claims priority to Chinese patent application No. 202311643222.0, filed on Dec. 4, 2023, the entire content of which is incorporated herein by reference.

### TECHNICAL FIELD

The present disclosure relates to the technical field of resonators, and in particular to a wafer-level packaged resonator and a preparation method therefor, and an electronic device.

### BACKGROUND

The traditional quartz crystal resonator structure is usually composed of a metal top cover, a quartz blank, and a ceramic base, and is packaged by vacuum or inert gas. The upper and lower surfaces of the quartz blank need to be evaporated or sputtered with electrodes, and are connected to pins of the ceramic base. Alternating voltage can be in communication with upper and lower electrodes of the quartz blank through pins, which makes the quartz blank produce inverse piezoelectric effect to generate vibration. Quartz crystal resonator is widely used in electronic industries such as mobile electronic devices and communication apparatuses due to its frequency accuracy and stability.

With the rapid development of mobile communication electronics, the demand for miniaturization of devices is getting higher and higher, and the miniaturization of the quartz crystal resonators is also imperative. However, if the size of the quartz crystal resonator under the traditional package structure needs to be further reduced, it will be limited by the greatly reduced yield and higher material and manufacturing cost. Therefore, in order to comply with the miniaturization trend of electronic devices, the wafer-level packaged resonator has gradually become a hot spot in the industry.

In related documents, a crystal resonator including a package cover plate, a package bottom plate and a blank arranged between the package cover plate and the package bottom plate is provided. The blank includes a substrate and pin ends, fully wrapped pin ends are formed at both ends of the substrate, and there is no need to provide pin ends outside the base, and meanwhile, the corresponding dispensing process or rolling welding process is omitted, thereby reducing the external size of the crystal resonator.

In the related art, there is a problem that the stability of the resonator is affected due to the influence of external vibration or stress.

### SUMMARY

In order to reduce the influence of external vibration or stress to improve the stability of a wafer-level packaged resonator, an objective of the present disclosure is to provide a wafer-level packaged resonator and a preparation method therefor, and an electronic device.

In a first aspect, a wafer-level packaged resonator provided by the present disclosure employs the following technical solution:

A wafer-level packaged resonator includes a wafer top cover, a wafer base, and a blank. The blank includes:
a resonant part;
an assembling part, sleeved on the periphery of the resonant part, where the blank is bonded and packaged between the wafer top cover and the wafer base through the assembling part; and
at least two connecting parts, respectively connected between the resonant part and the assembling part, where each connecting part includes at least one continuous bend.

By adopting the above technical solution, the resonant part and the assembling part of the blank are connected by at least two connecting parts, and each connecting part includes at least one continuous bend. Through the arrangement of the continuous bend, the attenuation effect of energy transfer of shock waves is improved, the influence of the external vibration or stress is reduced, and the stability of the wafer-level packaged resonator is improved, that is, the shock resistance of the wafer-level packaged resonator is improved. The problem that the bonding of the traditional wafer-level packaged resonator is more susceptible to external vibration or stress than the connection through a conductive adhesive is solved, and the shock resistance is improved while reducing the size.

Alternatively, each connecting part includes two continuous bends, the two continuous bends are connected at one end and then linearly connected to the resonant part, and the other ends of the two continuous bends are in surface connection with the assembling part in a deviation direction.

By adopting the above technical solution, the cooperative arrangement of the two continuous bends can improve the shock resistance of the connecting part. Further, the connecting part and the assembling part are connected through an expanded surface to ensure the stability of the whole apparatus. Meanwhile, the linear connection between the connecting part and the resonant part can weaken the energy transfer effect of the shock waves. The shock resistance is increased while comprehensively ensuring the stability.

Alternatively, a space of the assembling part for accommodating the resonant part includes 2n symmetrically arranged included angles, where n is greater than or equal to 2.

Each connecting part corresponds to one of the included angles of the assembling part, and one end of the connecting part is connected to two side surfaces of the corresponding included angle, respectively.

By adopting the above technical solution, each connecting part is set corresponding to one of the included angles, and is used to synchronously receive the vibration from two side surfaces of the corresponding included angle, thus improving the effect of receiving shock waves while enhancing the support for included angle connection.

Alternatively, each continuous bend includes:
a first bend, including an upper straight section with one end connected to the resonance part, a middle straight section arranged opposite to the upper straight section at intervals, and a first transition section connected between the upper straight section and the middle straight section, where the first transition section is an arc with a central angle of 90°, or a V shape with a right angle; and
a second bend, including a lower straight section arranged opposite to the middle straight section at intervals, a second transition section connected between the lower straight section and the middle straight section, and a connecting section connected to a free end of the second transition section and in surface connection with the assembling part, where the second transition section is an arc with a central angle of 90°, or a straight line perpendicular to the middle straight section and the lower straight section, respectively.

By adopting the above technical solution, the first bend and the second bend each include a bend with a 90° transition, and the 90°-transition structure is used to improve the effect of changing a vibration energy transfer direction. Further, the linear arrangement of the first transition section and the second transition section can further enhance the effect of changing the vibration energy transfer direction while satisfying a stress demand, thus improving the attenuation effect of energy transfer of the shock waves.

Alternatively, each of the wafer top cover, the wafer base and the blank is provided with m etched sidewalls, where m is greater than or equal to 2.

Metal layers are arranged on a portion of the wafer top cover opposite to the assembling part, a portion of the wafer base opposite to the assembling part, and two sides of the assembling part respectively opposite to the wafer top cover and the wafer base, and any etched sidewall.

Each of the metal layer on the wafer top cover, the metal layer on the wafer base and the metal layer on the assembling part is etched with an open circuit, such that each metal layer on the assembling part is only in communication with the metal layer on the corresponding etched sidewall.

By adopting the technical solution above, through the arrangement of the etched sidewall, the same metal layer is arranged between the etched sidewall and the corresponding body (the wafer top cover, the wafer base, and the blank). In combination with an open-circuit arrangement, each side surface of the assembling part fits with the metal layer on the etched sidewall to form an electrode lead-out structure, the process steps such as punching and metal filling are reduced, and the process steps are simplified.

Alternatively, the metal layer includes a chromium layer and a ruthenium layer, or a titanium layer and a gold layer.

By adopting the technical solution above, the arrangement of the ruthenium layer or titanium layer forms a barrier, which can weaken the diffusion between metals in the bonding process, improve the bonding effect between metal layers, and greatly improve the air tightness effect and yield after bonding.

Alternatively, the etched sidewall is arc-shaped.

By adopting the above technical solution, the arc design is conducive to etching molding, and can improve the yield of the product.

Alternatively, the resonant part and the space of the assembling part for accommodating the resonant part are both rectangular.

There are four connecting parts distributed at four corners of the resonant part, respectively.

Each of the wafer top cover, the wafer base and the blank is provided with four etched sidewalls corresponding to the four corners of the connecting parts.

The etched sidewalls in electrical communication with two metal layers on the assembling part are arranged at opposite corners of the corresponding assembling part, respectively.

By adopting the technical solution above, through the arrangement of the rectangular resonant part and the cooperation of the four connecting parts at four corners, the stability of the apparatus is improved while satisfying an effective stability demand. Further, in conjunction with the arrangement of the etched sidewall, when the formation of the electrode lead-out structure is satisfied, the cutting in the batch production process is convenient, and the manufacturing process is simplified.

In a second aspect, a preparation method for a wafer-level packaged resonator provided by the present disclosure employs the following technical solution:

A preparation method for a wafer-level packaged resonator includes the following steps:
S1. manufacturing a top cover assembly, a base assembly, and a blank assembly, respectively, where the manufacturing includes the following steps:
etching a wafer to form resonant units arranged in a matrix, where the resonant units corresponding to the blank assembly include a resonance part, and at least two connecting parts, and each connecting part includes at least one continuous bend;
etching the corresponding wafer at intervals in a circumferential direction of each resonant unit to form a group of through slots;
forming a metal layer on a non-resonant effective area of a bonding surface of the wafer and an etched sidewall of each through slot, respectively;
forming electrodes on both sides of the resonant unit corresponding to the blank assembly, respectively, where each electrode is in electrical communication with one of the etched sidewalls of the blank assembly;
S2. stacking and then bonding the top cover assembly, the base assembly and the blank assembly in turn to form a bond body; and
S3. cutting the bond body in a direction of connecting each group of through slots to form a wafer-level packaged resonator.

By adopting the technical solution above, firstly, the connecting parts are arranged, and each connecting part is defined to include at least one continuous bend, thus improving the shock resistance while satisfying the size reduction. Secondly, through the arrangement of the through slots, a metal layer is formed on the etched sidewall of each through slot while synchronously forming the metal layer on the non-resonant effective area. When the cutting is promoted, an electrode lead-out structure is formed, wafer-level packaging processing is optimized, and the process of punching the wafer before metal filling in similar scheme is avoided.

In a third aspect, an electronic device provided by the present disclosure employs the following technical solutions:

An electronic device includes a wafer-level packaged resonator.

By adopting the above technical solution, an electronic device including the wafer-level packaged resonator is provided, and the wafer-level packaged resonator has good shock resistance.

In conclusion, the present disclosure includes at least one of the following beneficial effects:
1. The arrangement of the connecting part including continuous bend can improve the attenuation effect of energy transfer of shock waves, reduce the influence of external vibration or stress, and improve the stability of the wafer-level packaged resonator. Further, the connecting part is defined to include a first bend and a second bend, both of which have right-angle bends, thus achieving better shock resistance in a small size range.
2. The three-layer arrangement of the metal layer weakens the diffusion between metals in the bonding process, which greatly improves the air tightness effect and yield after bonding.
3. With the arrangement of the open circuit in fit with the etched sidewall, each side surface of the assembling part is in fit with the metal layer on the etched sidewall to form an electrode lead-out structure, the process steps such as punching and metal filling are reduced, and the process steps are simplified. Further, the etched sidewall is arranged in a semi-arc shape to improve the yield of product.
4. The arrangement of a getter improves the sealing effect, and further, the getter is defined as a chromium layer and a gold layer which are arranged in sequence, such that the preparation process is simplified while ensuring the sealing effect.

### BRIEF DESCRIPTION OF THE DRAWINGS

FIG. 1 is a structural diagram of a wafer-level packaged resonator according to Embodiment 1 of the present disclosure;

FIG. 2 is an exploded view of a wafer-level packaged resonator according to Embodiment 1 of the present disclosure;

FIG. 3 is a structural diagram of a blank according to Embodiment 1 of the present disclosure for showing a side opposite to a wafer top cover;

FIG. 4 is a structural diagram of a blank according to Embodiment 1 of the present disclosure for showing a side opposite to a wafer base;

FIG. 5 is an enlarged view of part A in FIG. 4;

FIG. 6 is a structural diagram of a wafer top cover according to Embodiment 1 of the present disclosure;

FIG. 7 is a structural diagram of a wafer base according to Embodiment 1 of the present disclosure;

FIG. 8 is a structural diagram of a wafer according to Embodiment 2 of the present

### DISCLOSURE

In the drawings:

1—wafer top cover; 10—getter; 2—wafer base; 3—blank; 30—resonant part; 31—assembling part; 32—connecting part; 4—continuous bend; 40—first bend; 400—upper straight section; 401—middle straight section; 402—first transition section; 41—second bend; 410—lower straight section; 411—second transition section; 412—connecting section; 5—etched sidewall; 6—metal layer; 7—open circuit; 8—groove; 9—electrode; 90—conductive layer; 100—wafer; 101—through slot; 102—resonant unit.

### DETAILED DESCRIPTION OF THE EMBODIMENTS

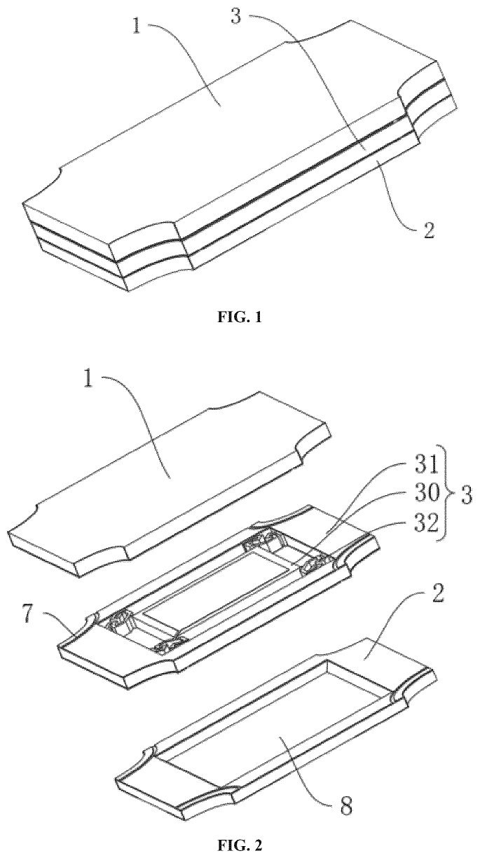

The present disclosure is further described below with reference to FIG. 1-FIG. 8.

### Embodiment 1

Embodiment 1 of the present disclosure provides a wafer-level packaged resonator, referring to FIG. 1 and FIG. 2, the wafer-level packaged resonator includes a wafer top cover 1, a wafer base 2 and a blank 3 which are bonded and packaged in turn.

### 1. About Blank 3:

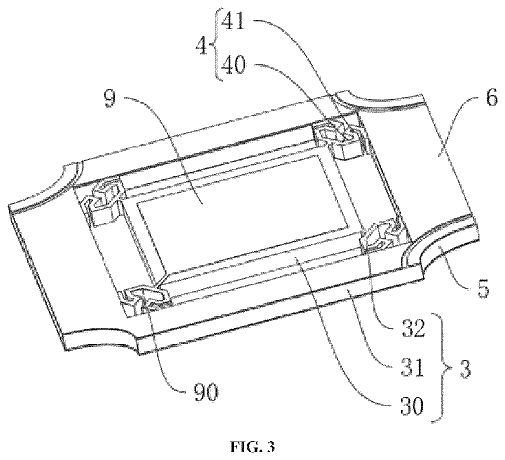

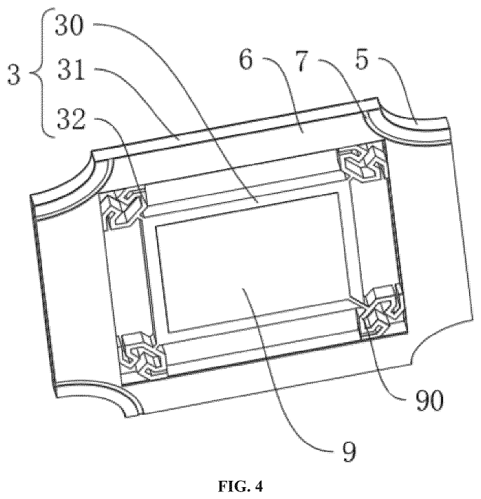

Referring to FIG. 3 and FIG. 4, the blank 3 is made of quartz, and includes a resonant part 30, an assembling part 31, and at least two connecting parts 32. The resonant part 30 is connected to the assembling part 31 through the at least two connecting parts 32, that is, the assembling part 31 is sleeved on the periphery of the resonant part 30, and the resonant part 30 and a space of the assembling part 31 for accommodating the resonant part 30 may specifically be square, rectangular, or circular, as long as the resonance can be generated. In a specific embodiment, the space of the assembling part 31 for accommodating the resonant part 30 includes 2n symmetrically arranged included angles, where n is greater than or equal to 2. In this embodiment, the resonant part 30 is rectangular, and the assembling part 31 for accommodating the resonant part 30 is a rectangle in fit with the resonant part 30. The at least two connecting parts 32 are connected between the resonant part 30 and the assembling part 31, respectively. Specifically, the number of the connecting parts 32 may be 2, 3, or 4, as long as the shock-resistant support is satisfied and the resonant part 30 is connected. In one of the specific embodiments, there are two connecting parts 32 which are respectively arranged at opposite corners of the rectangular resonant part 30. Exemplary, the connecting parts 32 can be respectively arranged at the centers of opposite edges of the rectangular resonant part 30. When the number of the connecting parts 32 is two, in a case that the energy of the shock wave is small, the excellent energy transfer effect can be achieved while the shock resistance is satisfied. In another specific embodiment, there are three connecting parts 32, which are respectively arranged at included angles of the rectangular resonant part 30. In this embodiment, there are four connecting parts 32, which are respectively arranged at the included angles of the rectangular resonant part 30, and have excellent shock resistance while satisfying the energy transfer.

Each connecting part 32 includes at least one continuous bend 4. In this embodiment, in order to improve the shock resistance of the connecting part 32, each connecting part 32 includes two continuous bends 4, the two continuous bends 4 are connected at one end and then linearly connected to the resonant part 30. Specifically, the two continuous bends 4 are connected at one end to protrude to form a connecting rod, and a free end of the connecting rod is connected to the resonant part 30. The other ends of the two continuous bends 4 are in surface connection the assembling part 31 in a direction away from each other. The connecting parts 32 can be correspondingly connected to a sidewall of the assembling part 31, or installed corresponding to the included angle of the assembling part 31. In this embodiment, each connecting part 32 is arranged corresponding to one of the included angles of the assembling part 31, and the other end of the connecting part 32 are connected to two side surfaces of the corresponding included angle, respectively.

In order to simplify the manufacturing process and improve the attenuation effect of energy transfer of the shock waves, in this embodiment, referring to FIG. 5, each continuous bend 4 includes a first bend 40, and a second bend 41. The first bend 40 includes an upper straight section 400 with one end connected to the resonance part, a middle straight section 401 arranged opposite to the upper straight section 400 at intervals, and a first transition section 402 connected between the upper straight section 400 and the middle straight section 401. The second bend 41 includes a lower straight section 410 arranged opposite to the middle straight section 401 at intervals, a second transition section 411 connected between the lower straight section 410 and the middle straight section 401, and a connecting section 412 connected to a free end of the second transition section 411 and in surface connection with the assembling part 31. The first transition section 402 and the second transition section 411 may be in smooth transition, specifically an arc with a central angle of 90°, or may be in non-smooth transition, specifically, the first transition section 402 is a V shaped with a right angle, and the second transition section 411 is a straight line perpendicular to the middle straight section 401 and the lower straight section 410, respectively.

The blank 3 is provided with m etched sidewalls 5, where m is greater than or equal to 2. One of the functions of the etched sidewalls 5 is to form an electrode 9 lead-out structure, so there are at least two etched sidewalls. The arrangement of the simultaneous etched sidewalls 5 can meet the requirement of cutting the whole wafer 100 to form a wafer packaged resonator monomer. In this embodiment, the blank 3 is arranged in a rectangular solid shape, and there are four etched sidewalls 5 opposite to each blank 3 at four corners of the blank 3. Structurally, the etched sidewall 5 may be linear, arc-shaped, wavy, etc. In order to improve the yield of the product, in this embodiment, the etched sidewall 5 of the blank 3 is arc-shaped.

Metal layers 6 are arranged on two sides of the assembling part 31 respectively opposite to the wafer top cover 1 and the wafer base 2, and any etched sidewall 5 on the blank 3. The metal layer 6 may be a chromium layer and a gold layer arranged away from the blank 3 in turn, or a chromium layer, a ruthenium layer or titanium layer and a gold layer arranged away from the blank 3 in turn. In this embodiment, the metal layer 6 on the blank 3 is a chromium layer, a ruthenium layer and a gold layer which are arranged in turn.

The metal layer 6 on the assembling part 31 is etched with an open circuit 7, such that each metal layer 6 on the assembling part 31 is only in communication with the metal layer 6 on a corresponding etched sidewall 5. In this embodiment, portions, corresponding to three etched sidewalls 5, of one of the metal layers 6 on the assembling part 31 are provided with open circuits 7, and portions, corresponding to three etched sidewalls 5, of the other metal layer 6 on the assembling part 31 are provided with open circuits 7, and the corner, which is not provided with the open circuit 7, of one metal layer 6 on the assembling part 31 and the corner, which is not provided with the open circuit 7, of the other metal layer 6 on the assembling part 31 are opposite corners.

### 2. About Wafer Top Cover 1 and Wafer Base 2:

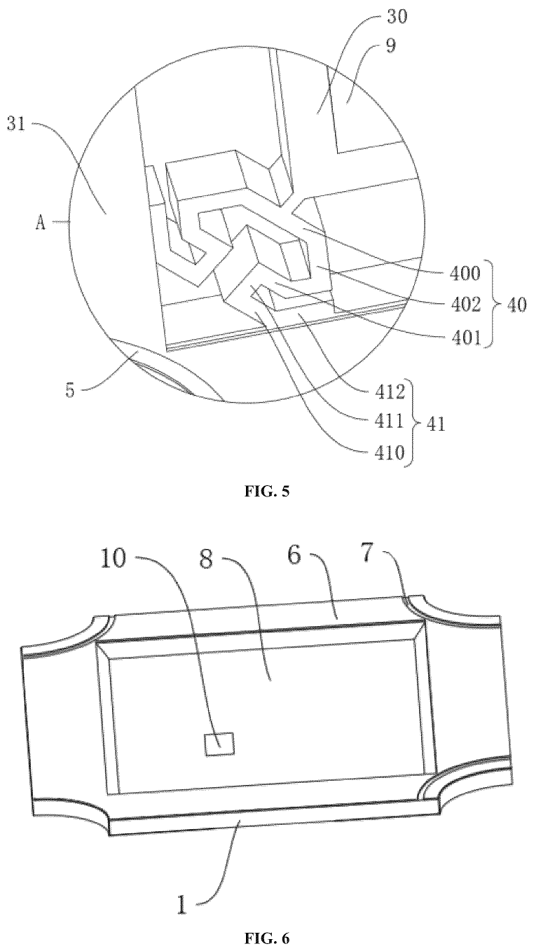

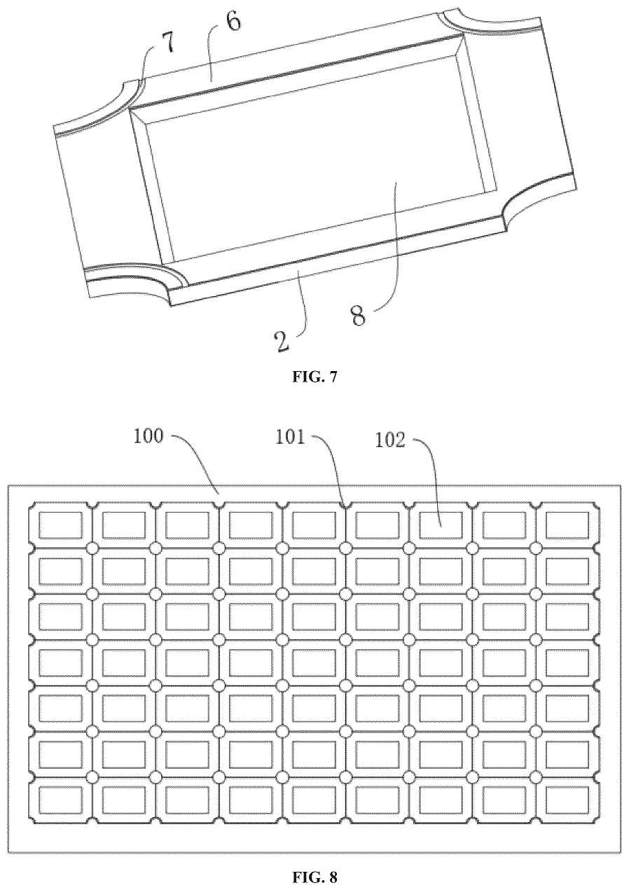

Referring to FIG. 6 and FIG. 7, the wafer top cover 1 and the wafer base 2 are both made of quartz or glass. In this embodiment, the wafer top cover 1 and the wafer base 2 are made of quartz.

One side of the wafer top cover 1 opposite to the blank 3, and one side of the wafer base 2 and the blank 3 each are provided with a vibration unit. The two vibration units, after being assembled and packaged, are in cooperation with the space of the assembling part 31 for accommodating the resonant part 30 to form a resonant cavity. The vibration units of the wafer top cover 1 and the wafer base 2 may be flat plates without the metal layer 6. In this case, the resonant cavity is formed by the space of the assembling part 31 for accommodating the resonant part 30. In this embodiment, the vibration units of the wafer top cover 1 and the wafer base 2 may be grooves 8, and the size of the groove 8 is provided to fit the space of the assembling part 31 for accommodating the resonant part 30.

The wafer top cover 1 is provided with etched sidewalls 5 corresponding to the etched sidewalls 5 of the blank 3, and the shape, the number and the position of etched side walls 5 are the same. That is, in this embodiment, the wafer top cover 1 is arranged as a rectangular solid shape, and four etched sidewalls 5 corresponding to each wafer top cover 1 are respectively located at the four corners of the wafer top cover 1, and are arc-shaped.

The wafer base 2 is provided with etched sidewalls 5 corresponding to the etched sidewalls 5 of the blank 3, and the shape, the number and the position of etched side walls 5 are the same. That is, in this embodiment, the wafer base 2 is arranged as a rectangular solid shape, and four etched sidewalls 5 corresponding to each wafer base 2 are respectively located at the four corners of the wafer base 2, and are arc-shaped.

Metal layers 6 are arranged on a portion of the wafer top cover 1 opposite to the assembling part 31, a portion of the wafer base 2 opposite to the assembling part 31, any etched sidewall 5 of the wafer top cover 1, and any etched sidewall 5 of the wafer base 2.

The metal layer 6 on the wafer top cover 1 is also etched with open circuits 7, which are in one-to-one correspondence with the open circuits 7 on the opposite metal layer 6 of the blank 3.

The metal layer 6 on the wafer base 2 is also etched with open circuits 7, which are in one-to-one correspondence with the open circuits 7 on the opposite metal layer 6 of the blank 3.

The blank 3 and the wafer top cover 1 are bonded through their metal layers 6, and the blank 3 and the wafer base 2 are bonded through their metal layers 6.

In order to improve the sealing effect after bonding, maintain vacuum, in another embodiment, the vibration unit of the wafer top cover 1 is correspondingly provided with a getter 10. The getter 10 is a nickel layer and a zirconium aluminum (ZrAl) layer sequentially arranged in a direction away from the wafer top cover 1. The getter 10 is a nickel layer and a zirconium vanadium iron (ZrVFe) layer sequentially arranged in a direction away from the wafer top cover 1. In this embodiment, the getter 10 is a chromium layer and a gold layer which are sequentially arranged in the direction away from the wafer top cover 1, and the preparation process is simplified while ensuring the sealing effect.

One side, opposite to a bonding surface thereof, of the wafer base 2 is provided with a bonding pad, and the bonding pad includes four layers of metals in turn in the direction away from the wafer base 2, and the four layers of metals are chromium, nickel, copper and gold in turn.

### 3. Arrangement of Electrode 9

A pair of electrodes 9 may be respectively arranged on both sides of the resonant part 30. In this embodiment, the electrode 9 is a rectangle in fit with the resonant part 30. Further, one of the connecting parts 32 is covered with a conductive layer 90 in communication with the corresponding electrode 9, and the electrode 9 and the conductive layer 90 may be made of gold.

In this embodiment, the conductive layer 90 is arranged on the connecting part 32 corresponding to the included angle where the open circuit 7 is not arranged, such that the conductive layer 90 can be connected to the metal layer 6 on the corresponding side of the blank 3 through the connecting part 32.

Alternatively, a pair of electrodes 9 can be respectively arranged on the resonant unit 102 of the wafer top cover 1 and the resonant unit 102 of the wafer base 2. One of the electrodes 9 is drawn to the wafer top cover 1 through a gold plating layer and in communication with the metal layer 6 on the wafer top cover 1. The other electrode 9 is drawn to the wafer base 2 through a gold plating layer and in communication with the metal layer 6 on the wafer base 2.

The implementation principle of Embodiment 1 of the present disclosure is as follows: each electrode 9 of the resonator is in electrical communication with the metal layer 6 of one of the etched sidewalls 5 through the corresponding conductive layer 90, and then is connected to a specific circuit through a bonding pad. The electrodes 9 on both sides of the resonant part 30 can generate voltage, and the blank 3 vibrates under the piezoelectric effect to output a specific frequency, thus achieving resonator function.

### Embodiment 2

Embodiment 2 of the present disclosure provides a preparation method for the wafer-level packaged resonator. Referring to FIG. 2 and FIG. 8, a preparation method for the wafer-level packaged resonator includes the following steps:

### 1. Preparation of a Blank Assembly

A wafer 100 with a certain specification is taken out, which is made of quartz.

Upper and lower surfaces of the taken-out wafer 100 are pretreated, and the pretreatment may be grinding and polishing to achieve the required thickness and flatness.

Resonant units 102 arranged in an array are formed on the wafer 100 by a photolithography process, and a group of through slots 101 are formed in a circumferential direction of each resonant unit 102 while forming the resonant unit 102. Referring to FIG. 8, the through slot 101 between four adjacent blanks 3 can be in through arrangement to form a through circular hole as a whole, thus increasing the subsequent treatment effect of the corresponding metal layer 6, and the corresponding through slot 101 may also be formed by cutting a circular hole at the edge. Each resonant unit 102 includes an accommodating space formed by etching, a resonant part 30 sleeved in the accommodating space, and at least two connecting parts 32 for connecting the resonant part 30 to the wafer 100 in a damping manner; and each connecting part 32 includes at least one continuous bend 4. In this embodiment, the blank 3 formed by subsequent cutting is rectangular, so a set of corresponding through slots 101 are distributed around the blank 3 formed by subsequent cutting, and the accommodating space and the resonant part 30 are both rectangular and coaxial with the corresponding blank 3. The connecting parts 32 are distributed at the four corners of the resonant part 30, and are connected to the four corners inside the corresponding accommodating space, respectively.

The metal layer 6 is formed on a non-resonant effective area of the bonding surface of the wafer 100 and an etched sidewall 5 of each through slot 101, respectively, and the metal layer 6 is synchronously etched to form an open circuit 7. The non-open circuit 7 parts of the two bonding surfaces of the wafer 100 are formed at the opposite corners of the blank 3 formed by subsequent cutting.

Electrodes 9 are formed on both sides of each resonant part 30 on the wafer 100, respectively. Further, one of the connecting parts 32 is covered with a conductive layer 90 in communication with the corresponding electrode 9, and the electrode 9 and the conductive layer 90 may be made of gold. In this embodiment, the conductive layer 90 is arranged on the connecting part 32 corresponding to the included angle where the open circuit 7 is not arranged, such that the conductive layer 90 can be connected to the metal layer 6 on the corresponding side of the blank 3 through the connecting part 32.

Therefore, the preparation of the blank assembly is completed.

### 2. Preparation of Top Cover Assembly

A wafer 100 with a certain specification is taken out, the wafer 100 may specifically be made of quartz, or glass.

Upper and lower surfaces of the taken-out wafer 100 are pretreated, and the pretreatment may be grinding and polishing to achieve the required thickness and flatness.

Resonant units 102 arranged in an array are formed on the wafer 100 by a photolithography process, each resonant unit 102 may specifically be a groove 8, and a group of through slots 101 are formed in a circumferential direction of each groove 8 while forming the groove 8. In this embodiment, the wafer top cover 1 formed by subsequent cutting is rectangular, so a set of through slots 101 are distributed around the wafer top cover 1 formed by subsequent cutting. The groove 8 is a rectangular groove and coaxial with the corresponding wafer top cover 1. Specifically, the photolithography process may specifically be as follows: a1. forming a first base layer by coating a film on the wafer 100, where the first base layer may specifically a chromium layer and a gold layer arranged in turn in this embodiment; a2. spin-coating a layer of photoresist on the first base layer, further carrying out selective irradiation exposure on the photoresist, developing and etching to make a pattern to be etched (for display) appear on the photoresist; and a3. obtaining the groove 8 and the through slot 10 by pattern etching based on development etching, and then removing an adhesive and the metal layer 6 by post-treatment.

A metal layer 6 is formed on the non-resonant effective area of the bonding surface of the wafer 100 (except the space occupied by the resonant unit 102) and the etched sidewall 5 of each through slot 101, respectively, and the open circuit 7 is formed at the same time. In this embodiment, the preparation method may be as follows: b1, forming the metal layer 6 on the wafer 100 by coating a film or evaporating, where the metal layer 6 may be chromium, ruthenium or titanium and gold arranged in turn in the direction away from along the wafer 100; b2, covering a layer of photoresist on the metal layer 6, further carrying out selective irradiation exposure on the photoresist, developing and etching to make a pattern to be etched (for displaying the resonant unit 102 interval, and the open circuit 7 interval) appear on the photoresist; and b3. based on the pattern etching of development etching, obtaining the etching of the metal at the corresponding open circuit 7 interval and the corresponding resonant unit 102 interval, and removing the adhesive by post-treatment. The open circuit 7 of the wafer 100 for manufacturing the top cover assembly of the wafer 100 overlaps with the open circuit 7 of the wafer 100 for manufacturing the blank assembly during bonding.

In order to improve the sealing effect after bonding, the vacuum is maintained. The method further includes forming a getter 10 on each resonant unit 102 of the wafer. The getter 10 is a nickel layer and a zirconium aluminum (ZrAl) layer sequentially arranged in a direction away from the wafer 100. The getter 10 is a nickel layer and a zirconium vanadium iron (ZrVFe) layer sequentially arranged in a direction away from the wafer top cover 1. In this embodiment, the getter 10 is a chromium layer and a gold layer which are sequentially arranged in the direction away from the wafer top cover 1, and the preparation process is simplified while ensuring the sealing effect.

In order to shield the external electromagnetic interference, the wafer 100 for manufacturing the top cover assembly has a shielding cover on one side opposite to its bonding surface. The shielding cover may have two layers of metals, which may be chromium and gold sequentially arranged in the direction away from the wafer 100, or chromium, nickel, copper and gold sequentially arranged in the direction away from the wafer 100 (this step may also be operated after cutting the bond body).

In conclusion, after the resonant unit 102 and the mating through slot 101 are formed in the wafer 100, the corresponding metal layer 6 and the getter 10 are formed by the photolithography process, thus completing the preparation of the top cover assembly.

### 3. Preparation of Base Assembly

The methods for selecting the wafer 100, preparing the resonant unit 102, forming the metal layer 6 and preparing the through slot 101 are the same as those of the top cover assembly. What needs to be adjusted is that the open circuit 7 of the wafer 100 for manufacturing the top cover assembly of the wafer 100 overlaps with the open circuit 7 of the wafer 100 for manufacturing the blank assembly during bonding, and the preparation of the base assembly does not include the getter 10.

A bonding pad is arranged on the side, opposite to the bonding surface thereof, of the wafer 100, and the bonding pad includes four layers of metals in turn in the direction away from the wafer 100, and the four layers of metals are chromium, nickel, copper and gold in turn (this step can also be operated after cutting the bond body).

4. The top cover assembly, the base assembly and the blank assembly are stacked in turn, and three layers of wafers 100 corresponding to the top cover assembly, the base assembly and the blank assembly are bonded together by a vacuum bonding technology to form a bond body.

5. The bond body is cut for separation by using laser cutting or blade cutting, which is cut in a direction of communicating each group of through slots 101 to form multiple wafer-level packaged resonators. The blank assembly is cut to form a blank corresponding to the wafer-level packaged resonator, the top cover assembly is cut to form a wafer upper cover 1 corresponding to the wafer-level packaged resonator, and the base assembly is cut to form a wafer base 2 corresponding to the wafer-level packaged resonator. In this embodiment, the cutting is specifically that four cutting edges for connecting the etched sidewalls 5 in the circumferential direction are formed for each wafer-level packaged resonator.

Therefore, the processing of the wafer-level packaged resonator is achieved.

The implementation principle of Embodiment 2 of the present disclosure is as follows: the top cover assembly, the base assembly and the blank assembly are respectively prepared from a raw material wafer 100 and then bonded and cut. During use, a pair of electrodes 9 of the resonator are respectively connected to a specific circuit through bonding pads, the electrodes 9 at both sides of the resonant part 30 generate voltage, and the blank 3 vibrates under the piezoelectric effect to output a specific frequency, thus achieve the function of the resonator.

### Embodiment 3

Embodiment 3 of the present disclosure provides an electronic device. The electronic device includes a wafer-level packaged resonator. The electronic device may specifically be a key element in the electronic device such as an oscillator, and a filter, as long as it is an electronic device including a wafer-level packaged resonator.

The embodiments of this specific embodiment are all preferred embodiments of the present disclosure, and the scope of protection of the present disclosure is not limited accordingly, where the same parts are denoted by the same reference numerals. Therefore, all equivalent changes made according to the structure, shape and principle of the present disclosure should be included in the scope of protection of the present disclosure.

What is claimed is:

1. A wafer-level packaged resonator, comprising a wafer top cover, a wafer base, and a blank, wherein the blank comprises:
a resonant part;
an assembling part, sleeved on the periphery of the resonant part, wherein the blank is bonded and packaged between the wafer top cover and the wafer base through the assembling part, and the resonant part and a space of the assembling part for accommodating the resonant part are both rectangular; and
connecting parts, wherein four connecting parts are respectively connected between the resonant part and the assembling part, and respectively arranged at four corners of the resonant part, each connecting part comprises two continuous bends, the two continuous bends are connected at one end and then linearly connected to the resonant part, and other ends of the two continuous bends are in surface connection with the assembling part in a direction away from each other; and
the space of the assembling part for accommodating the resonant part comprises four symmetrically arranged included angles, each connecting part corresponds to one of the included angles of the assembling part, and one end of the connecting part is connected to two side surfaces of the corresponding included angle, respectively;
each continuous bend comprises:
a first bend, comprising an upper straight section with one end connected to the resonant part, a middle straight section arranged opposite to the upper straight section at intervals, and a first transition section connected between the upper straight section and the middle straight section, wherein the first transition section is an arc with a central angle of 90°, or a V shape with a right angle; and
a second bend, comprising a lower straight section arranged opposite to the middle straight section at intervals, a second transition section connected between the lower straight section and the middle straight section, and a connecting section connected to a free end of the lower straight section and in surface connection with the assembling part, wherein the second transition section is an arc with a central angle of 90°, or a straight line perpendicular to the middle straight section and the lower straight section, respectively.

2. The wafer-level packaged resonator according to claim 1, wherein each of the wafer top cover, the wafer base and the blank are all provided with m etched sidewalls, where m is greater than or equal to 2;
metal layer are arranged on a portion of the wafer top cover opposite to the assembling part, a portion of the wafer base opposite to the assembling part, and two sides of the assembling part respectively opposite to the wafer top cover and the wafer base, and any etched sidewall;
each of the metal layer on the wafer top cover, the metal layer on the wafer base and the metal layer on the assembling part is etched with an open circuit, such that each metal layer on the assembling part is only in communication with the metal layer on the corresponding etched sidewall.

3. The wafer-level packaged resonator according to claim 2, wherein the metal layer comprises a chromium layer, a ruthenium layer and a gold layer, or a chromium layer, a titanium layer and a gold layer.

4. The wafer-level packaged resonator according to claim 2, wherein the etched sidewall is arc-shaped.

5. The wafer-level packaged resonator according to claim 2, wherein each of the wafer top cover, the wafer base and the blank is provided with four etched sidewalls corresponding to the connecting parts at four corners; and
the etched sidewalls in electrical communication with two metal layers on the assembling part are respectively arranged at opposite corners of the corresponding assembling part.

6. A preparation method for the wafer-level packaged resonator according to claim 1, comprising the following steps:
S1. manufacturing a top cover assembly, a base assembly, and a blank assembly, respectively, wherein the manufacturing comprises the following steps:
etching a wafer to form resonant unit arranged in a matrix, wherein the resonant units corresponding to the blank assembly comprise a resonant part, and four connecting parts;
etching the corresponding wafer at intervals in a circumferential direction of each resonant unit to form a group of through slots;
forming a metal layer on a non-resonant effective area of a bonding surface of the wafer and an etched sidewall of each through slot, respectively;
forming electrodes on both sides of the resonant unit corresponding to the blank assembly, respectively, wherein each electrode is in electrical communication with one of the etched sidewalls of the blank assembly;
S2. stacking and then bonding the top cover assembly, the base assembly and the blank assembly in turn to form a bond body; and
S3. cutting the bond body in a direction of connecting each group of through sots to form a wafer-level packaged resonator.

7. An electronic device, comprising the wafer-level packaged resonator according to claim 1.

8. An electronic device, comprising the wafer-level packaged resonator according to claim 2.

9. An electronic device, comprising the wafer-level packaged resonator according to claim 3.

10. An electronic device, comprising the wafer-level packaged resonator according to claim 4.

11. An electronic device, comprising the wafer-level packaged resonator according to claim 5.
